(19) United States
(12) Patent Application Publication
(10) Pub. No.: US 2014/0158886 A1
(43) Pub. Date: Jun. 12, 2014

(54) ELECTRON BEAM APPARATUS

(71) Applicant: Samsung Electronics Co., Ltd., Gyeonggi-do (KR)

(72) Inventors: Ogawa TAKASHI, Yokohama-si (JP); Sekiya HARUTAKA, Yokohama-si (JP); Usami YASUTSUGU, Yokohama-si (JP)

(73) Assignee: Samsung Electronics Co., Ltd., Gyeonggi-do (KR)

(21) Appl. No.: 14/096,775

(22) Filed: Dec. 4, 2013

(30) Foreign Application Priority Data
Dec. 4, 2012 (JP) 2012-265494

(51) Int. Cl. H01J 37/26

(52) U.S. Cl. CPC H01J 37/265
USPC 250/310

(57) ABSTRACT

In an electron beam apparatus having a plurality of electron beam columns arranged in a dense arrangement, a transfer device is inserted to operate the electron beam column so that the function and repair may be enhanced. An outer housing of the electron beam column includes a large diameter portion and a small diameter portion, and thus a gap may be formed near the small diameter portion. The transfer device penetrates the gap of the electron beam column at an outer periphery in a linear shape, and is connected to the electron beam column at a central portion.

### CROSS-REFERENCE TO RELATED APPLICATION

This application claims priority under 35 U.S.C. §119 to Japanese Patent Application No. 2012-265494, filed on Dec. 4, 2012 in the Japanese Intellectual Property Office, the contents of which are herein incorporated by reference in their entirety.

### BACKGROUND

1. Field

Example embodiments relate to an electron beam apparatus, and more particularly, an electron beam apparatus used for inspecting patterns of a semiconductor device.

2. Description of the Related Art

A semiconductor device that may be manufactured by forming circuit patterns on a wafer (semiconductor substrate) may be manufactured by forming patterns repeatedly. A method of forming the patterns includes forming a layer, coating a photoresist, exposing, developing, etching, removing the photoresist, cleaning, etc. If conditions for fabrication are not optimized in each process, the circuit patterns on the wafer may not be normally formed. For example, if problems are generated in forming the layer, particles may be generated and be adsorbed onto a surface of the wafer so as to generate defects. If conditions of focus or exposure time are not optimized during the exposing, a quantity or intensity of light emitted onto the photoresist may be too much or too little so as to generate electrical short, disconnection, etc.

If there are defects in a mask or a reticle during the exposing, the shape of the circuit patterns may not be normal. If a quantity of etching is not optimized or thin films or particles are generated in the etching, an opening may not be properly formed due to the electrical short, protrusions, isolated defects, etc. In the cleaning, an abnormal oxidation may occur at an edge portion of the patterns due to drainage conditions during dehydration. Thus, in the fabrication process for a wafer, it is helpful to detect at an early stage the failures of the circuit patterns due to various types of causes and provide feedback to the relevant process. Thus, an apparatus for inspecting defects has been recently important.

Conventionally, in a fabrication process of the semiconductor device such as a system LSI, a plurality of chips having the same circuit pattern are formed on a wafer. When detecting the failure of each circuit pattern, images of the circuit pattern between chips may be compared. When getting a minute circuit pattern, an electron beam may be used. For example, an inspection apparatus for inspecting circuit patterns of a general wafer may include an electron beam optical system for emitting an electron beam on the circuit pattern, or a cylindrical electron beam column including an electron beam detection system for detecting the emitted electron beam. The electron beam column emits an electron beam toward the circuit pattern, and detects a signal of a secondary electron obtained from the circuit pattern to get an image of the circuit pattern.

When the circuit pattern is compared to be inspected using the electron beam column, a large amount of time is needed to emit the electron beam on the plurality of chips formed on the whole surface of a wafer. Thus, in the conventional inspection apparatus of the circuit pattern, a plurality of electron beam columns are disposed so that the plurality of chips on the whole surface of the wafer may be inspected for a short time (refer to patent documents 1 and 2, which are both incorporated by reference herein in their entirety).

### CONVENTIONAL ART DOCUMENTS

### Patent Documents

Patent document 1: Japanese Laid-open Patent Publication No. 2005-121635, to Hisaya et al.

Patent document 2: Japanese Laid-open Patent Publication No. 1999-016967, to Kaoru et al.

### SUMMARY

In the conventional inspection apparatus including an electron beam column group consisting of a plurality of electron beam columns in a chamber, for example, a wiring connected to an electron beam column disposed at an outer periphery may be easily pulled out toward an outside of the chamber. However, a wiring connected to an electron beam column at a central portion of the electron beam column group has to be pulled out through a gap between the electron beam columns at the outer periphery. Thus, a length of the wiring between the chamber and a partition changes due to the position of the electron beam columns. A high frequency signal may be used as a signal for controlling the electron beam column, and depends on the oscillation generated by the reflection of the high frequency signal propagating through the wiring. A time delay of the signal transfer depends on the length of the wiring. Thus, if the lengths of the wiring of the electron beam columns are different from each other, inconvenient controlling operation is needed so that time deviation may not occur in controlling the respective electron beam columns.

Example embodiments provide an electron beam apparatus wherein a transfer device may be inserted to operate electron beam columns disposed with a high density, and the function and repair may be enhanced.

According to example embodiments, there is provided an electron beam apparatus. The electron beam apparatus includes a plurality of electron beam columns, and a transfer device. Each of the electron beam columns has an electron beam optical element including an electron beam optical system and a detection system. The electron beam optical system scans an electron beam on a surface of a sample, and the detection system detects an electron generated by scanning the electron beam. Each electron beam column includes an outer housing having a cylindrical shape with a large diameter portion and a small diameter portion. The transfer device is disposed at the small diameter portion, and is connected to the electron beam optical system of each electron beam column. The plurality of electron beam columns forms an electron beam column group. The electron beam column group includes a plurality of column rows having the plurality of electron beam columns of which large diameter portions are adjacent to each other at a given distance in a linear shape, and the column rows are arranged in parallel to each other. At least two neighboring column rows are disposed in a dense arrangement in which they are shifted to each other. The transfer device is inserted from an outside of the electron beam column group into a gap formed by the small diameter portion of each electron beam column in each column row.

In example embodiments, the transfer device may introduce an electrical signal to each electron beam column.

In example embodiments, the transfer device may introduce a high voltage electrical signal to each electron beam column, and penetrate the gap from the outside of the electron beam column group in a linear shape.

In example embodiments, the transfer device may introduce a high frequency electrical signal to each electron beam column. The transfer device may include a first transfer device penetrating the gap from the outside of the electron beam column group in a linear shape, and a second transfer device connected to the electron beam column at an outer periphery of the electron beam column group. The electron beam apparatus may further include a correction member for correcting the high frequency electrical signal flowing in the first and second transfer devices.

In example embodiments, the transfer device may transfer a high frequency electrical signal detected by the detection system to an outside of the electron beam column group. The transfer device may include a first transfer device penetrating the gap from the outside of the electron beam column group in a linear shape, and a second transfer device connected to the electron beam column at an outer periphery of the electron beam column group. The electron beam apparatus may further include a correction member for correcting the high frequency electrical signal flowing in the first and second transfer devices.

In example embodiments, the transfer devices may be installed at different heights from each other.

According to example embodiments, a large diameter portion and a small diameter portion may be formed in an electron beam column, so that a gap may be formed near the small diameter portion. When a plurality of column rows is arranged in a dense arrangement, a transfer device may penetrate the gap of the electron beam column at an outer periphery, so that a linear transfer device may be connected to the electron beam column arranged in a central portion. Thus, the transfer device may be inserted into all electron beam columns arranged in a dense arrangement, and the function and the repair may be enhanced.

### BRIEF DESCRIPTION OF THE DRAWINGS

Example embodiments will be more clearly understood from the following detailed description taken in conjunction with the accompanying drawings. FIGS. 1 to 5 represent non-limiting, example embodiments as described herein.

FIG. 1 shows the outline of an electron beam apparatus in accordance with example embodiments;

FIG. 2 is a cross-sectional view cut along a length direction of an electron beam column in accordance with example embodiments;

FIG. 3 is a cross-sectional view illustrating a plurality of electron beam columns when viewed from a top side;

FIG. 4 illustrates a cross-sectional view illustrating a plurality of electron beam columns when viewed from a lateral side; and

FIG. 5 is a cross-sectional view illustrating an arrangement of a plurality of electron beam columns when viewed from a lateral side in accordance with example embodiments.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

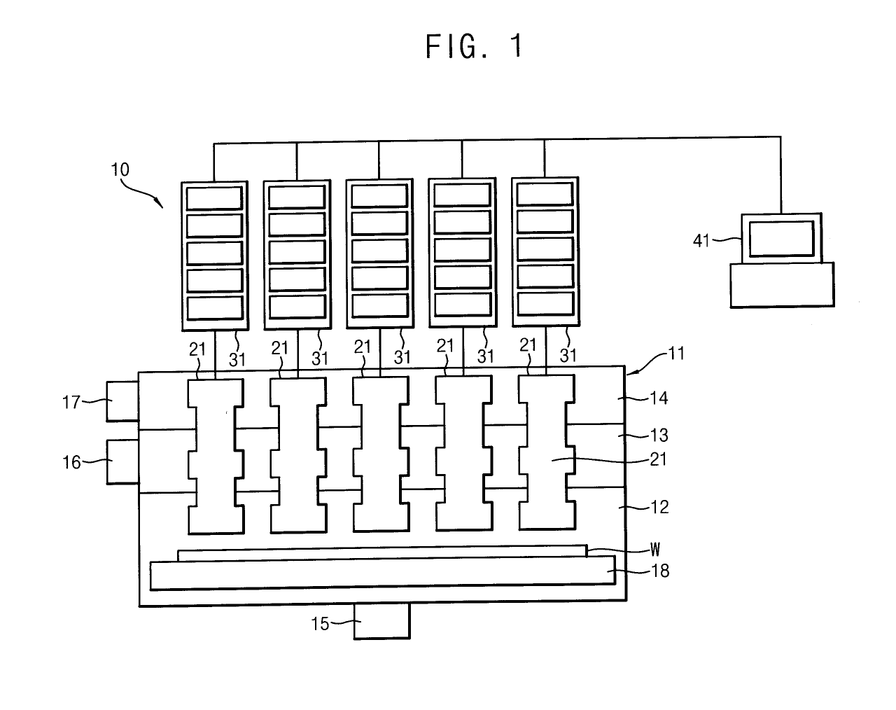

FIG. 1 shows the outline of an electron beam apparatus in accordance with example embodiments.

The electron beam apparatus (an inspection apparatus) 10 includes a chamber unit 11, a plurality of electron beam columns 21 contained in the chamber unit 11, a plurality of control power sources 31 connected to the electron beam columns 21, respectively, and a computer 41 connected to the control power sources 31.

The chamber unit 11 may include a first chamber 12 (wafer chamber), a second chamber 13 (central room chamber) and a third chamber 14 (electron gun chamber). The first, second and third chambers 12, 13 and 14 may form independent spaces from each other, which may be set up to different vacuum degrees from each other and be disposed adjacent to each other. Vacuum pumps 15, 16 and 17 are connected to the first, second and third chambers 12, 13 and 14, respectively so that the first, second and third chambers 12, 13 and 14 have given vacuum degrees, respectively. The electron beam columns 21 may be disposed through the first to third chambers 12, 13 and 14. The composition of the electron beam column 21 may be illustrated in detail.

A stage 18 for mounting a wafer W may be disposed in the first chamber 12 (wafer chamber). The wafer W to be inspected may be mounted on a surface of the stage 18. The stage 18 may move along a main surface of the wafer W in any direction, and may move the wafer W in a given direction at a given speed.

Each of the control power sources 31 may input a scan voltage for each electron beam column 21. For example, one of the control power sources 31 may be assigned to one of the electron beam columns 21 to form a pair. A signal output from the control power sources 31 may include a high voltage current, a high frequency current, etc. Each control power source 31 may further include a correction member (not shown). For example, the correction member may correct an error of the output signal, e.g., an error of a phase of a high frequency voltage or an error of a waiting time of a scan signal, or convert a control current circuit, e.g., a filter.

In one embodiment, the computer 41 inputs a control order for each electron beam column 21, and forms an image based on an output signal of a secondary electron beam reflecting the shape of a wiring that may be obtained by scanning an electron beam on the wafer W. Additionally, the computer 41 may compare images of a plurality of wiring patterns to confirm as to whether there is a difference between the images. When there is the difference between the images, the computer 41 may output a signal of an abnormal circuit pattern. The computer may be one of a variety of computing devices including hardware and software capable of performing the control and computational tasks described herein.

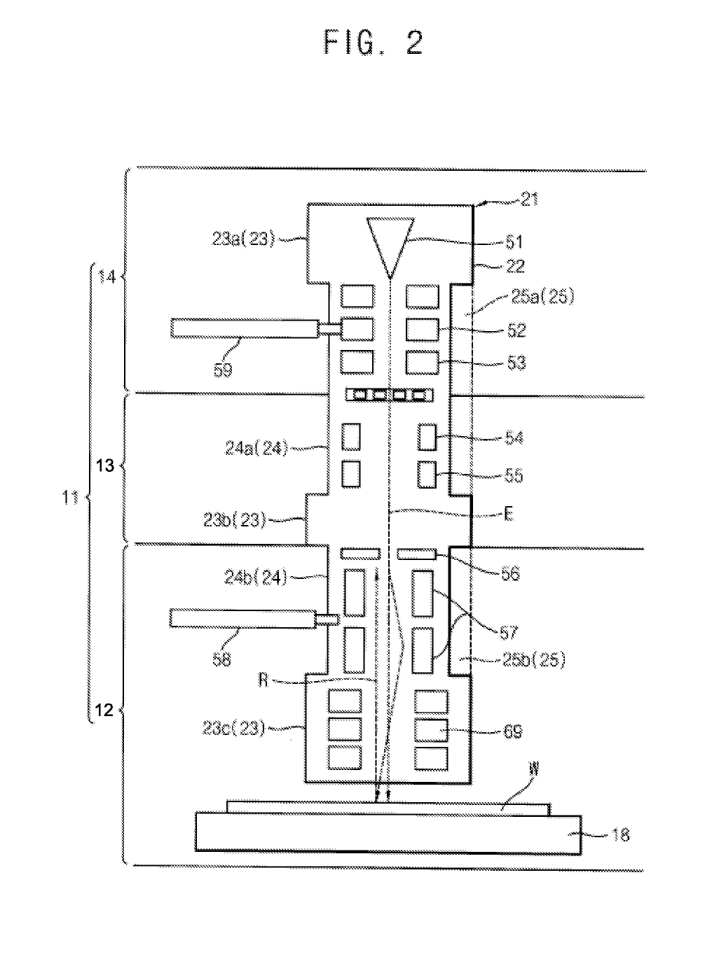

FIG. 2 is a cross-sectional view cut along a length direction of an electron beam column in accordance with example embodiments.

In one embodiment, the electron beam column 21 includes an outer housing 22 having a long and thin cylindrical shape. The outer housing 22 may include, e.g., a metal, and have a central mechanical axis. The metal may include, e.g., stainless steel, iron, phosphorous, bronze, aluminum, titanium, etc. The metal may further have a magnetic shield including an alloy having a high permeability, e.g., permalloy, mumetal, etc. The outer housing 22 may be equipped with a plurality of gas outlets (not shown) for vacuum exhausting an inside of the outer housing 22. An area through which the electron beam may penetrate may have an increased vacuum degree due to the gas outlets.

The outer housing 22 may include a large diameter portion 23 and a small diameter portion 24. In the present embodiment, three large diameter portions 23a, 23b and 23c and two small diameter portions 24a and 24b are connected to each other in a length direction of the outer housing 22 to form one outer housing 22. The small diameter portions 24a and 24b can be referred to as recessed portions or thin portions, and the large diameter portions 23a, 23b, and 23c can be referred to as protruding portions or thick portions.

Due to the shape of the outer housing 22, a gap 25 may be formed near the small diameter portion 24. For example, a gap 25a may be formed near a small diameter portion 24a between a large diameter portion 23a and a large diameter portion 23b. Each of the gaps 25a and 25b may be a space having a ring shape (a donut shape) near the small diameter portions 24a and 24b with respect to an imaginary cylindrical member having a diameter substantially the same as that of the large diameter portions 23a, 23b and 23c.

In certain example embodiments, the large diameter portions 23a, 23b and 23c composing the outer housing 22 may have a diameter of, e.g., about 30 to about 80 nm. In certain example embodiments, the small diameter portions 24a and 24b composing the outer housing 22 may have a diameter of, e.g., about 20 to about 60 nm. A difference between the diameter of the large diameter portions 23a, 23b and 23c and the diameter of the small diameter portions 24a and 24b may be set up to be equal to or larger than that of a first transfer device that may be illustrated later.

A plurality of electron beam optical elements may be contained in an inside of the outer housing 22 of the electron beam column 21. That is, an electron gun 51, a condenser lens 52, a electron beam collimator 53, a optical axis adjustment member 54, a blanking electrode 55, a secondary electron beam detector 56, a scan electrode 57 and an object lens 69 may be disposed in the inside of the outer housing 22. The secondary electron beam detector 56 may form a detection system, and the other optical elements may form an electron beam optical system. An end of the transfer device 58 may be connected toward the scan electrode 57. An electricity transfer device 59 may be further connected toward the condenser lens 52. The transfer device 58 may be further connected toward the secondary electron beam detector 56.

In certain embodiments, the transfer device 58 and the electricity transfer device 59 transfer an electrical signal from an outer device to a member performing an electrical operation, and transfer an electrical signal generated from the member performing the electrical operation to the outer device. The electrical signal may include, e.g., a high frequency electrical signal or a high voltage electrical signal. The transfer device 58 may further transfer a light from an outer device and transfer a light to the outer device, and may have a light guide. A transfer device that may have a mechanical operation may serve as the transfer device 58.

The electron gun 51 may include, e.g., a schottky type electron gun, a thermal field emission type electron gun, etc. An electron beam E may be emitted by applying an acceleration voltage to the electron gun 51. The condenser lens 52 and the electron beam collimator 53 may condense a light emitted from the electron gun 51 so as to obtain a desired current.

The optical axis adjustment member 54 may perform an astigmatism correction of the electron beam, or correct the position of the beam in the optical axis or the position of the beam scan on a sample.

The secondary electron beam detector 56 composing the detection system may detect a secondary electron beam R from the electron beam E having been scanned onto the wafer W according to the circuit pattern, and may output a high voltage or high frequency detection signal (secondary electron signal). The detection signal may be transferred to an outer device via the transfer device 58. The output signal transferred by the secondary electron beam detector 56 may be amplified, e.g., by a free amp and become an image digital data by an AD converter. The image digital data may be input into the computer 41 (refer to FIG. 1).

The scan electrode 57 (electron beam optical element) may receive a high frequency control signal (electrical signal), e.g., a high frequency current of about 0 to about 400V from an outer device, and deflect the electron beam E. The electron beam E may be deflected by applying a signal to the scan electrode 57, and the electron beam E may be scanned on a main surface of the wafer W along a given direction. The high frequency control signal may be introduced from an outer device to the scan electrode 57 via the transfer device 58. The object lens 69 may condense the electron beam E deflected by the scan electrode 57 onto the main surface of the wafer W.

By the above composition, in one embodiment, an electron beam E emitted from the electron gun 51 is scanned onto the main surface of the wafer W, and the secondary electron beam R reflecting the shape, composition or electric charge of the circuit pattern is detected by the secondary electron beam detector 56. An image of the circuit pattern on the main surface of the wafer W may be obtained by processing the detection signal of the detected secondary electron beam R using the computer 41 via a free amp or an AD converter.

In certain embodiments, among the electron beam optical elements, the electron gun 51 and/or the object lens 69 having a relatively large diameter are disposed at the large diameter portions 23a and 23c. Further, among the electron beam optical elements, the condenser lens 52, the electron beam collimator 53, the optical axis adjustment member 54 and/or the blanking electrode 55 are disposed at the small diameter portion 24a. Likewise, the secondary electron beam detector 56 (detection system) and the scan electrode 57 having a relatively small diameter may be disposed at the small diameter portion 24b.

The electron beam optical elements or the stage 18 may be contained in one of the chambers of the chamber unit 11 according to the desired vacuum degree. For example, in one embodiment as shown in FIG. 2, the electron gun 51 or the condenser lens 52, which may require the highest vacuum degree so as to emit the electron beam E, are be disposed in the third chamber 14 (electron gun chamber), which may be set up as the highest vacuum degree. The electron beam collimator 53, the optical axis adjustment member 54 and the blanking electrode 55 are disposed in the second chamber 13 (central chamber), which may have a second high vacuum degree next to the third chamber 14. The secondary electron beam detector 56 (detection system), the scan electrode 57, the object lens 69 and the stage 18 for mounting the wafer W are disposed in the first chamber 12 (wafer chamber), which may have a relatively low vacuum degree. Thus, in one embodiment, none of the electron beam optical elements, the stage 18, or the wafer W are disposed under a high vacuum condition at a level at which the electron beam E may be emitted.

Hereinafter, a layout of a plurality of electron beam columns according to certain embodiments is illustrated.

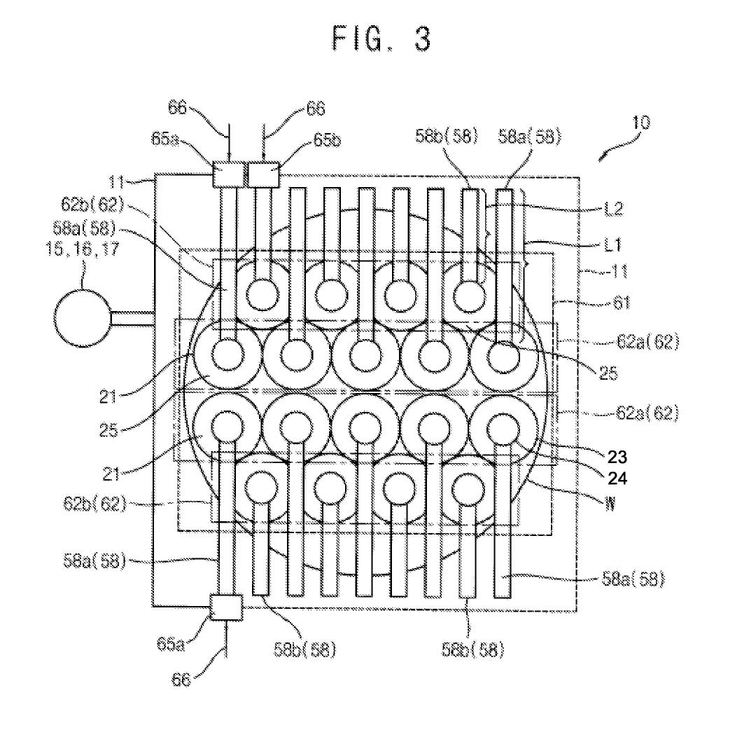

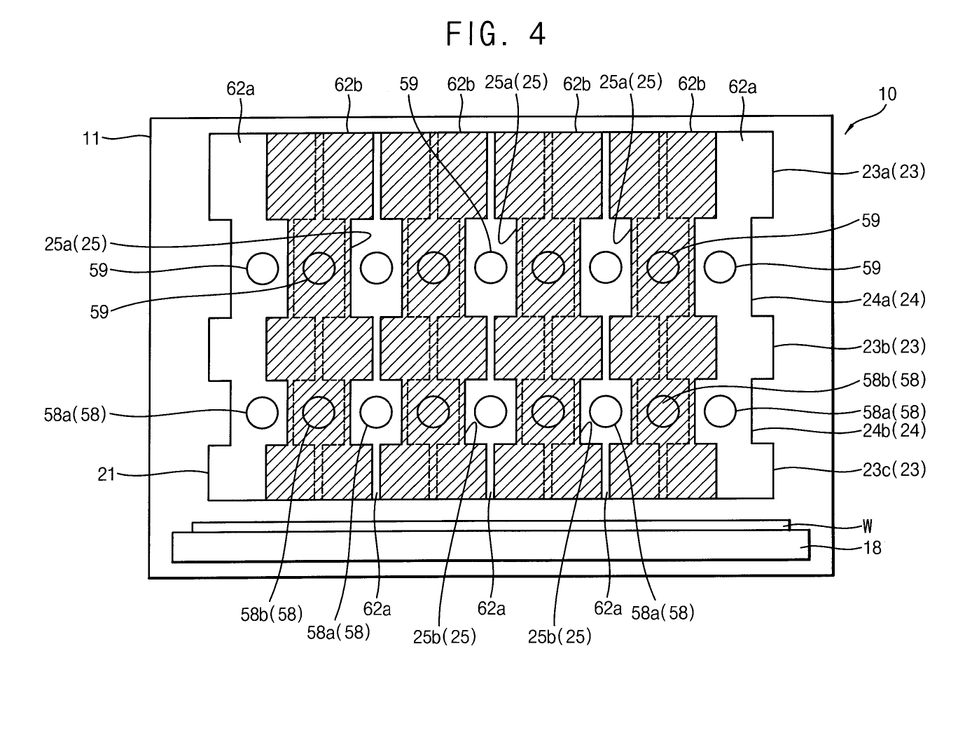

FIG. 3 is an exemplary cross-sectional view illustrating a plurality of electron beam columns when viewed from a top side. FIG. 3 illustrates a cross-section of the electron beam columns near the position of the transfer device 58 of FIG. 2, according to one embodiment. FIG. 4 illustrates a cross-sectional view illustrating a plurality of electron beam columns when viewed from a lateral side, according to one embodiment.

The electron beam apparatus 10 includes a plurality of electron beam columns 21, e.g., 18 electron beam columns 21 in the present embodiment, and an electron beam column group 61 including the 18 electron beam columns 21 may be formed.

The electron beam column group 61 includes a plurality of electron beam column rows 62 having a plurality of electron beam columns 21 of which large diameter portions 23 may be adjacent to each other at a given distance in a linear shape. The column rows 62 may be arranged in parallel to each other. For example, in the embodiment in FIG. 3, two column rows 62a each of which includes 5 electron beam columns 21 and two column rows 62b each of which includes 4 electron beam columns 21 are formed. A distance between the large diameter portions 23 in the same electron beam column 21 may be set up to, e.g., several millimeters.

Among the column rows 62, two column rows disposed at an outer periphery of the electron beam column group 61 may be referred to as a second column row 62b, and two column rows disposed at a central portion of the electron beam column group 61 between the two second column rows 62b may be referred to as a first column row 62a. The first and second column rows 62a and 62b adjacent to each other arranged in parallel may be disposed in a zigzag arrangement or in a honeycomb arrangement in which they are shifted to each other by about half of the diameter of the large diameter portion 23 of the electron beam column 21 so as to be arranged densely. In the present embodiment shown in FIG. 3, one first column row 62a and one second column row 62b may form a pair, and two pairs are disposed to be symmetrical to each other.

A first end of a second transfer device 58b among the transfer devices 58 for transferring an electrical signal may be connected to the second column row 62b disposed at the outer periphery of the electron beam column group 61. The first end of the second transfer device 58b may be connected to the scan electrode 57 in the small diameter portion 24 of the electron beam column 21 included in the second column row 62b, and may transfer a high frequency signal to the scan electrode 57. A second end of the second transfer device 58b may be connected to a connector 65b in the chamber unit 11. The connector 65b may include a seal between the air and vacuum, and an input signal line 66 from the control power source 31 may be connected thereto. Thus, a high frequency signal output from the control power source 31 may be input from the input signal line 66 via the transfer device 58b to the scan electrode 57 of the electron beam column 21 in the second column row 62b, and may deflect the electron beam E in an arbitrary direction.

A first end of a first transfer device 58a among the transfer devices 58 for transferring an electrical signal may be connected to the first column row 62a disposed at the central portion of the electron beam column group 61. The first transfer device 58a may be disposed to penetrate through the gap 25 in a linear shape from the outer periphery of the electron beam column group 61. For example, in the neighboring electron beam columns 21 of the second column row 62b, the first transfer device 58a may pass by the gap 25 between the small diameter portions 24, and may penetrate through the second column row 62b at the outer periphery toward the first column row 62a at the central portion of the electron beam column group 61 and reach the first column row 62a.

A second end of the first transfer device 58a may be connected to the connector 65a (vacuum port) at the chamber unit 11. The connector 65a may include a seal between the air and vacuum, and the input signal line 66 from the control power source 31 (refer to FIG. 1) may be connected thereto. Thus, in one embodiment, a high frequency signal output from the control power source 31 is input from the input signal line 66 via the transfer device 58a to the scan electrode 57 of the electron beam column 21 in the first column row 62a, and deflects the electron beam E in an arbitrary direction. The vacuum pumps 15, 16 and 17 may be preferably disposed at a side of the chamber unit 11 at which the transfer device 58 is not formed.

An exemplary operation and effect of the electron beam apparatus having the above composition is explained hereinafter.

The electron beam column 21 included in the electron beam apparatus 10 in accordance with example embodiments may include the large diameter portion 23 and a small diameter portion 24, so that the gap 25, which is a space having a ring shape (donut shape), may be formed near the small diameter portion 24 between the large diameter portions 23. For example, a plurality of column rows, e.g., when the first column row 62a and the second column row 62b are arranged in a dense arrangement (in a zigzag arrangement, a honeycomb arrangement), the gap 25 may serve as an opening penetrating through the second column row 62b between neighboring electron beam columns 21 in the second column row 62b disposed at the outer periphery. Thus, the transfer device 58 may be connected to each electron beam column 21 included in the first column row 62a disposed at the central portion of the electron beam column group 61 via the gap 25 from an outside of the second column row 62b in a linear shape.

In the electron beam apparatus 10, in order to enhance the throughput of the inspection of the circuit pattern, the electron beam may be scanned at a high speed, or blanking (cutting of the beam) may be performed at a horizontal return part. These may be performed by providing electrical signals to the electrode via the transfer device 58 (introduction terminal, vacuum inner signal line). It is known that the oscillation generated due to the reflection or the time delay may depend on the length of the signal line for the frequency signal.

Thus, for example, a first length L1 (refer to FIG. 3) of the first transfer device 58a connected to each electron beam column 21 included in the first column row 62a may be constant according to the above composition in accordance with example embodiments. Likewise, a second length L2 (refer to FIG. 3) of the second transfer device 58b connected to each electron beam column 21 included in the second column row 62b may be also constant. The lengths of the first transfer devices 58a and the lengths of the second transfer devices 58b may be constant, so that adjusting the electrical parameters of the electron beam column 21 is not needed and a time for adjusting the electron beam apparatus may be reduced. Additionally, in the aspect of the scanning method, an electrode may be used, however, the method may not be limited thereto, and e.g., a magnetic field deflection using a coil may be used.

A high voltage may be applied to the electron gun 51, the scan electrode 57 and the wafer W being an object to be inspected in the electron beam apparatus 10. Generally, when a high voltage is used, a distance of about 0.1 mm per 1 kV for a space, and a distance of about 1 mm per 1 kV for an insulator are needed. Thus, due to the transfer device 58 having the above composition, a sufficient space for the column row 62 is available, and a high voltage may be provided to the electron beam column 21 via the transfer device 58.

Further, the electricity transfer device 59 or a terminal 65 to which a high voltage may be applied may be degenerated due to a long time use so that discharge may occur. However, in accordance with example embodiments, the electricity transfer device 59 or the terminal 65 has a linear shape so as to be easily replaced with another one with no disassembly thereof

The secondary electron beam detector 56 (detection system) may have the following operation and effect. In the electron beam apparatus 10, in order to enhance the throughput of the inspection of the circuit pattern, the electron beam should be scanned at a high speed and simultaneously the secondary electron signal emitted from a sample should be detected at a high speed, which may be performed by providing electrical signals generated by the secondary electron beam detector 56 using a control unit 31 including a free amp or an AD converter, and thus may be performed via the transfer device 58 of the electrical signal (introduction terminal, vacuum inner signal line). It is known that the oscillation generated due to the reflection or the time delay may depend on the length of the signal line for the frequency signal.

Thus, the first length L1 (refer to FIG. 3) of the first transfer device 58a connected to each electron beam column 21 included in the first column row 62a may be constant according to the above composition in accordance with example embodiments. Likewise, the second length L2 (refer to FIG. 3) of the second transfer device 58b connected to each electron beam column 21 included in the second column row 62b may be also constant. The lengths of the first transfer devices 58a and the lengths of the second transfer devices 58b may be constant, so that adjusting the electrical parameters of the electron beam column 21 is not needed and a time for adjusting the electron beam apparatus may be reduced.

Additionally, the outer housing 22 of the electron beam column 21 may have a cylindrical shape including metal and further include a magnetic shield, and thus, in one embodiment, even though the transfer device 58 may penetrate through the gap 25 between the electron beam columns 21, the transfer device 58 does not affect the electron beam in the neighboring electron beam column 21. When a high voltage or a high speed electrical signal is applied, it may deflect the induced magnetic field or electromagnetic field in an unexpected direction. However, the electron beam column 21 may include metal so that the influence of the high voltage or the high speed electrical signal may be reduced, and the inspection of the circuit pattern with a high exactness may be performed.

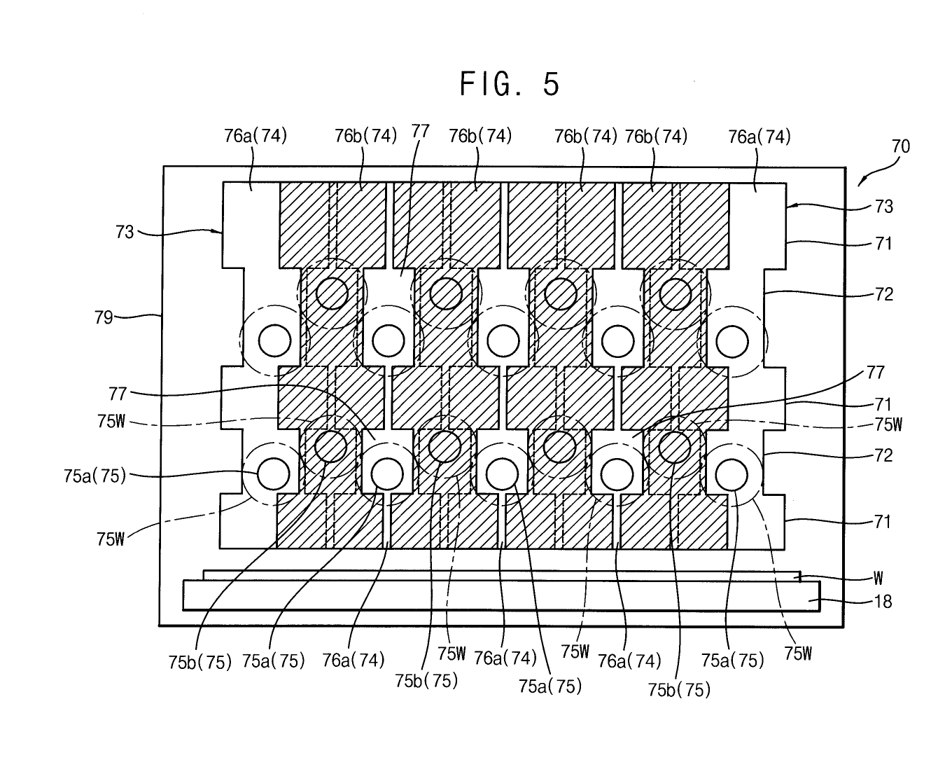

FIG. 5 is a cross-sectional view illustrating an arrangement of a plurality of electron beam columns when viewed from a lateral side in accordance with example embodiments. In an electron beam apparatus 70 of the present embodiment, in an electron beam column 74 having an outer housing 73 including a large diameter portion 71 and a small diameter portion 72, a transfer device 75 may be connected to the small diameter portion 72. The transfer device 75 may input or output, e.g., an electrical signal into or from the electron beam optical elements in the electron beam column 74.

Among two column rows 76a and 76b arranged in a dense form, a first transfer device 75a connected to the column row 76a at a central portion may penetrate through a gap 77 near the small diameter portion 72 in a linear shape. The first transfer device 75a and a second transfer device 75b connected to the column row 76b at an outer periphery may have different heights. For example, the first transfer device 75a and the second transfer device 75b may be disposed at different heights along a direction of length of the electron beam column 74 in a zigzag form.

When a plurality of transfer devices 75, e.g., the first transfer device 75a and the second transfer device 75b are disposed at different heights from each other, near a connector (vacuum port) of a chamber unit 79, even if the transfer device 75 includes an enlarged portion 75W having a radius larger than the gap 77, neighboring transfer devices 75 are disposed with no interference with each other. When the electron beam column 74 is accessed due to the control operation of the electron beam apparatus 70, a space between the transfer devices 75 is large so as to be easily repaired.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. An electron beam apparatus, comprising:
a plurality of electron beam columns having an electron beam optical element including an electron beam optical system and a detection system, the electron beam optical system scanning an electron beam on a surface of a sample, the detection system detecting an electron generated by scanning the electron beam, and each electron beam column including an outer housing having a cylindrical shape with a large diameter portion and a small diameter portion; and
a transfer device disposed at the small diameter portion, the transfer device being connected to the electron beam optical system of each electron beam column,
wherein the plurality of electron beam columns form an electron beam column group,
wherein the electron beam column group includes a plurality of column rows having the plurality of electron beam columns of which large diameter portions are adjacent to each other at a given distance in a linear shape, the column rows are arranged in parallel to each other, and at least two neighboring column rows are disposed in a dense arrangement in which they are shifted to each other,
and wherein the transfer device is inserted from an outside of the electron beam column group into a gap formed by the small diameter portion of each electron beam column in each column row.

2. The electron beam apparatus of claim 1, wherein the transfer device introduces an electrical signal to each electron beam column.

3. (canceled)

4. The electron beam apparatus of claim 1, wherein the transfer device introduces a high frequency electrical signal to each electron beam column, and includes a first transfer device penetrating the gap from the outside of the electron beam column group in a linear shape, and a second transfer device connected to the electron beam column at an outer periphery of the electron beam column group,
and further comprising a correction member for correcting the high frequency electrical signal flowing in the first and second transfer devices.

5. The electron beam apparatus of claim 1, wherein the transfer device transfers a high frequency electrical signal detected by the detection system to an outside of the electron beam column group, and includes a first transfer device penetrating the gap from the outside of the electron beam column group in a linear shape, and a second transfer device connected to the electron beam column at an outer periphery of the electron beam column group,
and further comprising a correction member for correcting the high frequency electrical signal flowing in the first and second transfer devices.

6. The electron beam apparatus of claim 1, wherein the transfer devices are installed at different heights from each other.

7. The electron beam apparatus of claim 1, wherein the transfer device introduces a high voltage electrical signal to each electron beam column, and penetrates the gap from the outside of the electron beam column group in a linear shape.

8. The electron beam apparatus of claim 2, wherein the transfer device introduces a high voltage electrical signal to each electron beam column, and penetrates the gap from the outside of the electron beam column group in a linear shape.
